(19) United States
(12) Patent Application Publication
(10) Pub. No.: US 2026/0223544 A1
(43) Pub. Date: Jul. 30, 2026

(54) DISPLAY PANEL AND DISPLAY DEVICE

(71) Applicants: Chengdu BOE Optoelectronics Technology Co., Ltd., Chengdu, Sichuan Province (CN); BOE Technology Group Co., Ltd., Beijing (CN)

(72) Inventors: Cheng Zeng, Beijing (CN); Dan WANG, Beijing (CN); Guangri YU, Beijing (CN); Lulin MA, Beijing (CN); Zhenye WEI, Beijing (CN); Qiyun WANG, Beijing (CN); Xingjian CHENG, Beijing (CN)

(21) Appl. No.: 19/145,236

(22) PCT Filed: Aug. 12, 2024
(86) PCT No.: PCT/CN2024/111545

§ 371 Date: Jul. 2, 2025

(30) Foreign Application Priority Data
Sep. 22, 2023 (CN) 202311238150.1

(51) Int. Cl. H10K 59/122; H10K 59/38; H10K 59/80

(52) U.S. Cl. CPC H10K 59/122; H10K 59/38; H10K 59/873

(57) ABSTRACT

A display panel includes: a base substrate including pixel regions arranged in an array; light-emitting devices in one-to-one correspondence with the pixel regions; a first pixel definition layer located on a side of the light-emitting devices away from the base substrate and including first opening regions in one-to-one correspondence with the pixel regions, the reflectivity of the first pixel definition layer to light in a wavelength range of 400 nm-700 nm being greater than 20%, the first pixel definition layer including a first side surface surrounding the first opening region, and the first side surface being a concave surface which recesses towards the first pixel definition layer; and quantum dot patterns on the side of the light-emitting devices away from the base substrate and in at least some of the first opening regions.

### CROSS-REFERENCE TO RELATED APPLICATIONS

This disclosure is a national phase entry under 35 U.S.C. § 371 of International Application No. PCT/CN2024/111545, filed on Aug. 12, 2024, which claims priority to Chinese Patent Application No. 202311238150.1, filed to the China National Intellectual Property Administration on Sep. 22, 2023, and entitled “Display Panel and Display Device”, the entire contents of which are incorporated herein by reference.

### TECHNICAL FIELD

The present disclosure relates to the field of display technology, and in particular to a display panel and a display device.

### BACKGROUND

The combination of Quantum Dots (QD) and Organic Light Emitting Diode (OLED) technologies has the advantages of high color gamut, excellent viewing angle, and high contrast.

In QD-OLED devices with more mature technology at this stage, the QD layer is located above the OLED device and is used for color conversion. The QD-OLED device also includes a pixel definition layer on the same layer as the QD layer. The pixel definition layer is used to define the sub-pixel region. The pixel definition layer needs to have a high absorbance to prevent color crosstalk between adjacent QD layers and ensure the color purity of the QD-OLED device. The pixel definition layer is usually a black pixel definition layer added with black dye. The black pixel definition layer is difficult to be penetrated by ultraviolet light during ultraviolet curing. Therefore, the thickness of the black pixel definition layer that can be cured by ultraviolet light is limited. The thickness of the QD layer is limited by the thickness of the pixel definition layer. Within a certain thickness range, the conversion rate of the QD layer increases with the increase of the film thickness of the QD layer. Since the thickness of the black pixel definition layer is limited, the conversion rate of the QD layer cannot be increased by increasing the thickness of the QD layer.

### SUMMARY

Embodiments of the present disclosure provide a display panel and a display device to improve the conversion rate of quantum dots.

Embodiments of the present disclosure provide a display panel.

The display panel includes a base substrate including a plurality of pixel regions arranged in an array along a first direction and a second direction. The pixel region comprises a plurality of sub-pixel regions. The first direction intersects the second direction.

The display panel includes a plurality of light-emitting devices located on a side of the base substrate and corresponding one-to-one to the sub-pixel regions.

The display panel includes a first pixel definition layer located on a side of the light-emitting devices away from the base substrate and including first opening regions corresponding one-to-one to the sub-pixel regions. The reflectivity of the first pixel definition layer to light in a wavelength range of 400 nanometers to 700 nanometers is greater than 20%. The first pixel definition layer includes a first side surface surrounding the first opening region. The first side surface is a concave surface recessed in the first pixel definition layer.

The display panel includes a plurality of quantum dot patterns located on a side of the light-emitting devices away from the base substrate and located in at least some of the first opening regions.

In some embodiments, cross-sectional areas of the first opening region parallel to a plane where the base substrate is located gradually increase in a direction perpendicular to the base substrate and pointing from the base substrate to the first pixel definition layer.

In some embodiments, the first side surface is a portion of a spherical surface.

In some embodiments, the first pixel definition layer includes a first surface facing the base substrate and a second surface facing away from the base substrate. The width d1 of the first opening region on the first surface and the width d2 of the first opening region on the second surface in the first direction or in the second direction, and the thickness h1 of the first pixel definition layer in the direction perpendicular to the base substrate satisfy:

$$\frac{d 2}{2} = \sqrt{{( \frac{d 1}{2} )}^{2} + h {1}^{2}} .$$

In some embodiments, in the first direction or in the second direction, the width d1 of the first opening region on the first surface, the width d2 of the first opening region on the second surface, and the maximum width L1 of the first pixel definition layer satisfy:

$$\frac{d 2}{2} \leq \frac{d 1}{2} + \frac{L 1}{3} .$$

In some embodiments, the maximum width L1 of the first pixel definition layer in the first direction or in the second direction and the thickness h1 of the first pixel definition layer in the direction perpendicular to the base substrate satisfy:

$$\frac{1}{2} \leq \frac{L 1}{h 1} \leq 1 .$$

In some embodiments, the width d1 of the first opening region on the first surface in the first direction or in the second direction and the thickness h1 of the first pixel definition layer in the direction perpendicular to the base substrate satisfy:

$$\frac{1}{12} \leq \frac{h 1}{d 1} \leq \frac{1}{4} .$$

In some embodiments, the thickness h1 of the first pixel definition layer in a direction perpendicular to the base substrate is greater than or equal to 10 micrometers and less than or equal to 20 micrometers.

In some embodiments, the display panel further includes a color filter layer.

The color filter layer is located on a side of the quantum dot patterns away from the base substrate. The thickness of the color filter layer in the direction perpendicular to the base substrate is greater than or equal to 1 micrometer and less than or equal to 4 micrometers.

In some embodiments, the display panel further includes a plurality of encapsulation layers.

The plurality of encapsulation layers are located between the first pixel definition layer and the light-emitting devices. At least one of the plurality of encapsulation layers includes: a number of n low-refractive index encapsulation sub-layers and a number of n+1 high-refractive index encapsulation sub-layers, here n is an integer greater than or equal to 1. The refractive index of the high-refractive index encapsulation sub-layer is greater than the refractive index of the low-refractive index encapsulation sub-layer.

The low-refractive index encapsulation sub-layers and the high-refractive index encapsulation sub-layers are arranged alternately.

In some embodiments, the high-refractive index encapsulation sub-layer includes an inorganic material.

In some embodiments, the high-refractive index encapsulation sub-layer includes one or a combination of the following: silicon nitride, silicon oxide, or silicon oxynitride.

In some embodiments, the refractive index of the high-refractive index encapsulation sub-layer is greater than or equal to 1.6 and less than or equal to 1.85.

In some embodiments, the low-refractive index encapsulation sub-layer includes an organic material.

In some embodiments, the low-refractive index encapsulation sub-layer includes one of or a combination the following: acrylic resin, epoxy resin, phenolic resin, polyamide resin, polyimide resin, unsaturated polyester resin, polyphenylene resin, polyphenylene sulfide resin, or benzocyclobutene.

In some embodiments, the refractive index of the low-refractive index encapsulation sub-layer is greater than or equal to 1.4 and less than or equal to 1.5.

In some embodiments, at least one of the low-refractive index encapsulation sub-layers further includes a plurality of scattering particles.

In some embodiments, the mass percentage of the scattering particles is greater than or equal to 5% and less than or equal to 10%.

In some embodiments, the plurality of scattering particles includes one or a combination of the following: zinc oxide particles, titanium dioxide particles, hollow silica dioxide particles, non-hollow silica dioxide particles, nanosilicate particles, or porogen particles.

In some embodiments, the refractive index of the low-refractive index encapsulation sub-layer is greater than or equal to 1.1 and less than or equal to 1.4.

In some embodiments, the encapsulation layer closest to the quantum dot pattern includes the low-refractive index encapsulation sub-layers and the high-refractive index encapsulation sub-layers.

In some embodiments, n=1, or n=2.

In some embodiments, the light-emitting devices are blue light-emitting devices. The sub-pixel regions include: multiple red sub-pixel regions, multiple blue sub-pixel regions, and multiple green sub-pixel regions. The quantum dot patterns are only located in the first opening regions corresponding to the red sub-pixel regions and the green sub-pixel regions.

A display device provided by embodiments of the present disclosure includes the display panel provided by the embodiments of the present disclosure.

### BRIEF DESCRIPTION OF DRAWINGS

In order to more clearly illustrate the technical solutions in the embodiments of the present disclosure, the drawings required for use in the description of the embodiments will be briefly introduced below. Obviously, the drawings described below are only some embodiments of the present disclosure. For ordinary technicians in this field, other drawings can be obtained based on these drawings without paying creative work.

FIG. 1 is a graph showing the relationship between the conversion rate of the quantum dot pattern and the film thickness of the quantum dot pattern provided by an embodiment of the present disclosure.

FIG. 2 is a schematic diagram of the structure of a display panel provided by an embodiment of the present disclosure.

FIG. 3 is a graph showing an OD value of a black pixel definition layer and an OD value of a first pixel definition layer provided by an embodiment of the present disclosure.

FIG. 4 illustrates reflectivity curve diagrams of a black pixel definition layer and a first pixel definition layer provided by an embodiment of the present disclosure.

FIG. 5 is a schematic diagram of the structure of a display panel provided by the related art.

FIG. 6 is a schematic diagram of the structure of another display panel provided by an embodiment of the present disclosure.

FIG. 7 is a schematic diagram showing a comparison between a first side surface being a portion of a spherical surface and a first side surface being a plane provided by an embodiment of the present disclosure.

FIG. 8 is a schematic diagram of a first opening region of a display panel provided by an embodiment of the present disclosure.

FIG. 9 is a schematic diagram of a first opening region of another display panel provided by an embodiment of the present disclosure.

FIG. 10 is a schematic diagram of a first opening region of another display panel provided by an embodiment of the present disclosure.

FIG. 11 is a schematic diagram of a first opening region of another display panel provided by an embodiment of the present disclosure.

FIG. 12 is a schematic diagram of a first opening region of another display panel provided by an embodiment of the present disclosure.

FIG. 13 is a schematic diagram of a first opening region of another display panel provided by an embodiment of the present disclosure.

FIG. 14 is a schematic diagram of a first opening region of another display panel provided by an embodiment of the present disclosure.

FIG. 15 is a schematic diagram of a first opening region of another display panel provided by an embodiment of the present disclosure.

FIG. 16 is a schematic diagram of a first opening region of another display panel provided by an embodiment of the present disclosure.

FIG. 17 is a schematic diagram of a first opening region of another display panel provided by an embodiment of the present disclosure.

FIG. 18 is a schematic diagram of a first opening region of another display panel provided by an embodiment of the present disclosure.

FIG. 19 is a schematic diagram of a first opening region of another display panel provided by an embodiment of the present disclosure.

FIG. 20 is a schematic diagram of a first opening region of another display panel provided by an embodiment of the present disclosure.

FIG. 21 is a schematic diagram of a first opening region of another display panel provided by an embodiment of the present disclosure.

FIG. 22 is a schematic diagram of the structure of another display panel provided by an embodiment of the present disclosure.

FIG. 23 is a schematic diagram of the structure of another display panel provided by an embodiment of the present disclosure.

FIG. 24 is a schematic diagram of the structure of another display panel provided by an embodiment of the present disclosure.

FIG. 25 is a schematic diagram of the structure of another display panel provided by an embodiment of the present disclosure.

FIG. 26 is a schematic diagram of the structure of another display panel provided by an embodiment of the present disclosure.

FIG. 27 illustrates reflectivity curve diagrams of an encapsulation layer for different wavebands provided by an embodiment of the present disclosure.

FIG. 28 is a schematic diagram of the structure of another display panel provided by an embodiment of the present disclosure.

FIG. 29 illustrates reflectivity curve diagrams of another encapsulation layer for different wavebands provided by an embodiment of the present disclosure.

FIG. 30 is a schematic diagram of the structure of another display panel provided by an embodiment of the present disclosure.

FIG. 31 is a schematic diagram of the structure of another display panel provided in an embodiment of the present disclosure.

FIG. 32 illustrates reflectivity curve diagrams of another encapsulation layer for different wavebands provided by an embodiment of the present disclosure.

### DETAILED DESCRIPTION

In order to make the purpose, technical solution and advantages of the embodiments of the present disclosure more clear, the technical solution of the embodiments of the present disclosure will be clearly and completely described below in conjunction with the drawings of the embodiments of the present disclosure. Obviously, the described embodiments are only part of the embodiments of the present disclosure, rather than all the embodiments. Furthermore, the embodiments in the present disclosure and the features in the embodiments may be combined with each other without conflict. Based on the described embodiments of the present disclosure, all other embodiments obtained by those of ordinary skill in the art without creative work are within the scope of protection of the present disclosure.

Unless otherwise defined, technical or scientific terms used in the present disclosure should have the common meanings understood by a person having ordinary skills in the field to which the present disclosure belongs. The terms “first”, “second” and the like used in the present disclosure do not indicate any order, quantity or importance, but are only used to distinguish different components. The words “include” or “comprise” and the like mean that the elements or objects preceding the word include the elements or objects listed after the word and their equivalents, but do not exclude other elements or objects. The words “connect” or “connected” and the like are not limited to physical or mechanical connections, but may include electrical connections, whether direct or indirect.

It should be noted that the size and shape of each figure in the accompanying drawings do not reflect the actual proportion, and the purpose is only to illustrate the contents of the present disclosure. And the same or similar reference numerals throughout represent the same or similar elements or elements having the same or similar functions.

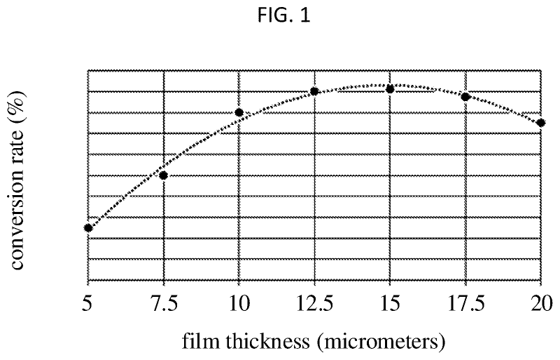

In the related art, the pixel definition layer located at the same layer as the quantum dot patterns is usually a black pixel definition layer added with black dye. The black pixel definition layer has a high absorbance and can effectively prevent color crosstalk between adjacent quantum dot patterns to ensure the color purity of the display product. However, the thickness of the black pixel definition layer that can be cured by ultraviolet light is approximately 10 micrometers (μm) to 11 μm, that is, the thickness of the black pixel definition layer that can be cured by ultraviolet light is limited. The thickness of the quantum dot pattern is limited by the thickness of the pixel definition layer. The relationship between the conversion rate of the quantum dot pattern and the film thickness of the quantum dot pattern is shown in FIG. 1. Within a certain thickness range, when the thickness of the quantum dot pattern does not exceed 15 μm, the conversion rate of the quantum dot pattern increases with the increase of the film thickness of the quantum dot pattern. However, the maximum thickness of the black pixel definition layer is much less than 15 μm. Since the thickness of the black pixel definition layer is limited, it is not possible to increase the thickness of the quantum dot pattern by increasing the thickness of the black pixel definition layer to improve the conversion rate of the quantum dot pattern.

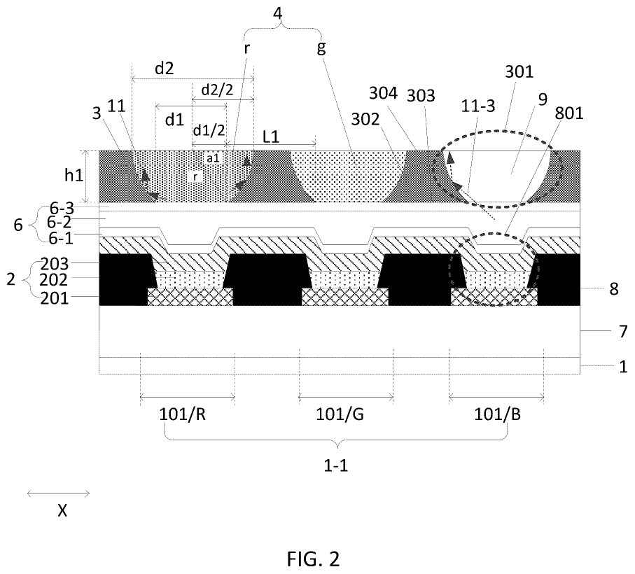

Embodiments of the present disclosure provide a display panel, as shown in FIG. 2.

The display panel includes a base substrate 1. The base substrate 1 includes a plurality of pixel regions 1-1 arranged in an array along a first direction X and a second direction Y (not shown). Each pixel region 1-1 includes a plurality of sub-pixel regions 101. The first direction X intersects the second direction Y. For example, the first direction X is perpendicular to the second direction Y.

The display panel includes a plurality of light-emitting devices 2. The light-emitting devices are located on a side of the base substrate 1 and correspond one-to-one to the sub-pixel regions 101.

The display panel includes a first pixel definition layer 3 located on a side of the light-emitting device 2 away from the base substrate 1. The first pixel definition layer 3 includes first opening regions 301 corresponding one-to-one to the sub-pixel regions 101. The reflectivity of the first pixel definition layer 3 to light in the wavelength range of 400 nanometers to 700 nanometers is greater than 20%. The first pixel definition layer 3 includes a first side surface 302 surrounding the first opening region 301. The first side surface 302 is a concave surface recessed in the first pixel definition layer 3.

The display panel includes a plurality of quantum dot patterns 4 located on a side of the light-emitting devices 2 facing away from the base substrate 1. The quantum dot patterns 4 are located in at least some of the first opening regions 301.

In the display panel provided by the embodiments of the present disclosure, the reflectivity of the first pixel definition layer to light in the wavelength range of 400 nm to 700 nm is greater than 20%. That is, the first pixel definition layer is a pixel definition layer without black dye. For example, the first pixel definition layer is a gray pixel definition layer. The first pixel definition layer is provided with first opening regions. The quantum dot patterns are located in at least some of the first opening regions. That is, the first pixel definition layer and the plurality of quantum dot patterns are located in the same layer. Compared with the black pixel definition layer in the related art, since the first pixel definition layer does not contain black dye, the first pixel definition layer set thicker can also be penetrated and cured by ultraviolet light. Therefore, compared with the related art, the thickness of the first pixel definition layer can be increased, thereby increasing the thickness of the quantum dot pattern and improving the conversion rate of the quantum dot pattern. In addition, the reflectivity of the first pixel definition layer is greater than that of the black pixel definition layer. The light emitted by the quantum dot pattern will be reflected when it reaches the first pixel definition layer. The first side surface of the first pixel definition layer surrounding the first opening region is a concave surface. The light emitted by the quantum dot pattern will be reflected after reaching the concave surface. The reflected light is emitted toward the front side of the display panel, i.e., the light emitting side of the display panel. The light reflected by the first side surface is fully utilized, thereby improving the light utilization rate of the display panel and the front light extraction efficiency.

In an implementation, the first pixel definition layer includes scattering particles, so that the film layer appears gray to obtain a gray pixel definition layer. The scattering particles include, for example, titanium oxide (TiO₂) particles.

In some embodiments, as shown in FIG. 2, the pixel region 1-1 includes a red sub-pixel region R, a blue sub-pixel region B, and a green sub-pixel region G.

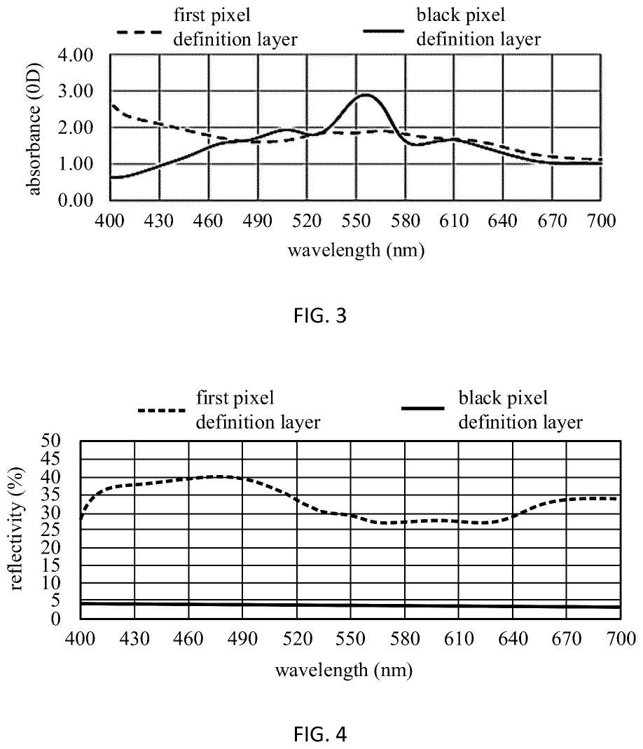

It should be noted that the pixel definition layer located on the same layer as the quantum dot patterns not only has the function of dividing sub-pixels, but also needs to have a high absorbance to prevent color crosstalk between adjacent quantum dot patterns. Usually, the measurement unit for absorbance is expressed as OD. OD stands for optical density, which means the light density absorbed by the detected object. OD=Ig (1/T), where T is the transmittance. The OD of the first pixel definition layer, i.e., the gray pixel definition layer, and the OD of the black pixel definition layer are shown in FIG. 3. It can be seen that in the blue light band, i.e., 400 nanometers (nm) to 480 nm, the OD of the first pixel definition layer is higher than that of the black pixel definition layer, and the OD of the first pixel definition layer is ≥1.6, i.e., only 2% of the blue light can pass through the first pixel definition layer. In the green light band, i.e., 520 nm to 570 nm, the OD of the black pixel definition layer is higher than that of the first pixel definition layer, and the OD of the first pixel definition layer is close to 2, indicating that only 1% of the green light can pass through the first pixel definition layer. In the red light band, i.e., 600 nm to 690 nm, the OD of the black pixel definition layer is almost the same as that of the first pixel definition layer. According to FIG. 3 and the above discussion, the first pixel definition layer has the same effect as the black pixel definition layer on light absorption in the 400 nm to 700 nm waveband. Therefore, the first pixel definition layer used in the embodiments of the present disclosure can also prevent color crosstalk between adjacent quantum dot patterns.

It should be noted that, in the display panel provided by the embodiments of the present disclosure, the quantum dot pattern is used to absorb the light emitted by the light-emitting device to radiate light of a desired color. Specifically, the color of the light radiated by the quantum dot pattern is the same as the color of the sub-pixel region corresponding to the quantum dot pattern.

In some embodiments, the light-emitting devices are blue light-emitting devices. As shown in FIG. 2, the quantum dot patterns 4 are only located in the first opening regions 301 corresponding to the red sub-pixel region R and the green sub-pixel region G.

Specifically, the quantum dot pattern 4 in the first opening region 301 corresponding to the red sub-pixel region R is a red light quantum dot pattern r that absorbs blue light and radiates red light. The quantum dot pattern 4 in the first opening region 301 corresponding to the green sub-pixel region G is a green light quantum dot pattern g that absorbs blue light and radiates green light.

In an implementation, the material of the quantum dot pattern includes a core-shell quantum dot structure. The core material in the core-shell quantum dot structure may be, for example, cadmium selenide (CdSe) or indium phosphide (InP). The shell material in the core-shell quantum dot structure may be, for example, zinc sulfide (ZnS).

In some embodiments, since the light-emitting devices are blue light-emitting devices, as shown in FIG. 2, the blue sub-pixel region B does not need to be provided with a quantum dot pattern and the display panel can also achieve full-color display.

In some embodiments, as shown in FIG. 2, the display panel may further include a transparent filling structure 9 for filling the first opening region 301 corresponding to the blue sub-pixel region B.

In an implementation, the transparent filling structure includes, for example, a transparent resin material.

It should be noted that, as shown in FIG. 2, when the light 11-3 emitted by the light-emitting device 2 passes through the filling structure 9 and reaches the first side surface 302, it will still be reflected and emitted toward the front side of the display panel. That is, although the region corresponding to the blue sub-pixel region B does not include the quantum dot pattern, the side surface of the first opening region 301 surrounding the blue sub-pixel region B is a portion of the spherical surface, which can still improve the front light extraction efficiency of the blue sub-pixel region. That is, in the display panel provided by the embodiments of the present disclosure, the first side surface being a portion of a spherical surface can improve the front light extraction efficiency of each sub-pixel region, thereby improving the front light extraction efficiency of the entire display panel, improving the display effect, and reducing power consumption.

It should be noted that the reflectivity of the black pixel definition layer and the reflectivity of the first pixel definition layer are shown in FIG. 4. It can be seen that the reflectivity of the black pixel definition layer in the entire visible light band, i.e., the range of 400 nm to 700 nm, is ≤5%. The reflectivity of the first pixel definition layer in the blue light band, i.e., the range of 400 nm to 480 nm, is approximately 35%, in the green light band, i.e., the range of 520 nm to 570 nm, is approximately 30%, and in the red light band, i.e., the range of 600 nm to 690 nm, is approximately 30%. The above data obtained according to FIG. 4 indicate that the red light or green light emitted from the quantum dot patterns and incident on the side surface of the first pixel definition layer will be reflected. In the display panel provided by the embodiments of the present disclosure, the first side surface of the first pixel definition layer is set as a concave surface, so as to fully utilize the reflected light of the concave surface and guide it to the front side, which is beneficial to improving the light utilization rate and improving the front light extraction efficiency of the display panel.

In some embodiments, as shown in FIG. 2, cross-sectional areas of the first opening region 301 parallel to a plane where the base substrate 1 is located gradually increase in a direction perpendicular to the base substrate 1 and pointing from the base substrate 1 to the first pixel definition layer 3. That is, the farther away from the base substrate 1, the larger the cross-sectional area of the first opening region 301 in the first pixel definition layer 3.

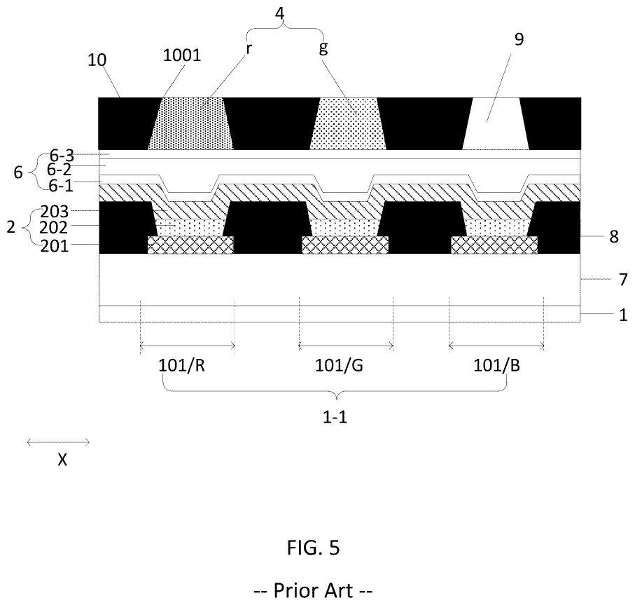

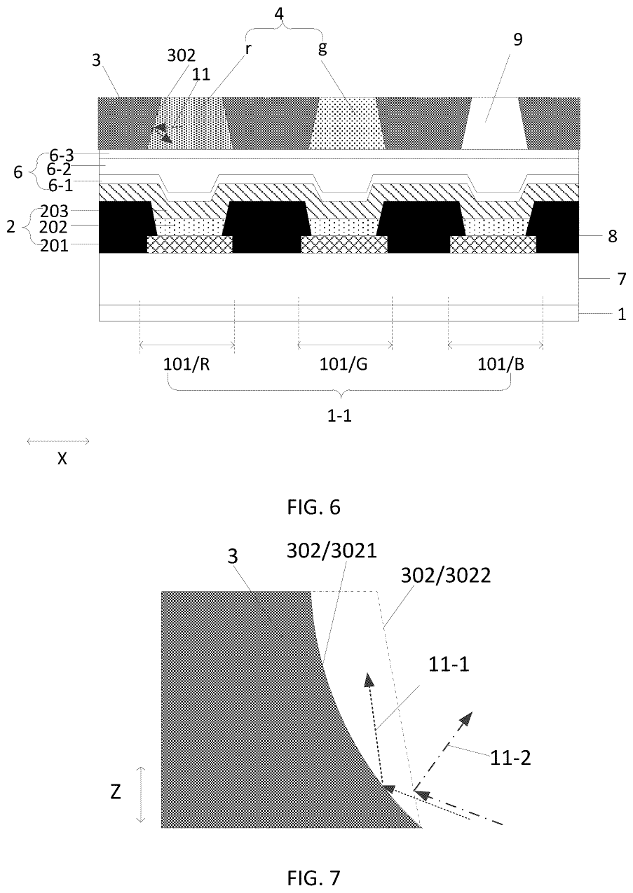

In the related art, as shown in FIG. 5, the side surface of the black pixel definition layer 10 surrounding the first opening region 301 is a slope 1001. The slope 1001 faces the base substrate 1. According to the reflectivity curve of the black pixel definition layer as shown in FIG. 4, light is almost completely absorbed after reaching the surface of the slope 1001, which affects the light utilization rate of the display panel. If the black pixel definition layer 10 shown in FIG. 5 is directly replaced by the first pixel definition layer 3 without changing the shape of the side surface, as shown in FIG. 6, most of the light 11 reaching the first side surface 302 of the first pixel definition layer 3 is reflected toward the base substrate 1, and most of the reflected light still cannot be used to increase the front light extraction efficiency of the display panel.

In the display panel provided by the embodiments of the present disclosure, the first side surface is a concave surface, and cross-sectional areas of the first opening regions parallel to the plane where the base substrate is located gradually increase. That is, the first side surface faces the front side of the display panel, so that the light reaching the concave surface is reflected and emitted more toward the front side of the display panel, thereby avoiding that the reflected light reaching the concave surface is mostly reflected to the back side of the display panel, thereby improving the light utilization rate and the front light extraction efficiency of the display panel.

In some embodiments, as shown in FIG. 2, the first side surface 302 is a portion of a spherical surface.

It should be noted that, as shown in FIG. 7, although the first side surface 302 is a slope 3022 facing the light emitting side, and the reflected light 11-2 of the slope 3022 can be emitted toward the front side of the display panel, the propagation direction of the light after reaching the portion of the spherical surface is different from the propagation direction of the light after reaching the slope. As shown in FIG. 7, when the first side surface 302 is a portion of the spherical surface 3021 facing the light emitting side, the angle between the reflected light 11-1 of the portion of the spherical surface 3021 and the direction perpendicular to the base substrate, that is, the Z direction in the figure, is small and can even be 0, while the angle between the reflected light 11-2 of the slope 3022 and the Z direction is large. That is, in the display panel provided by the embodiments of the present disclosure, when the first side surface 302 is a portion of the spherical surface 3021 facing the light emitting side, it is more conducive to improving the front viewing angle and the Z-direction viewing angle brightness of the display panel, and is conducive to improving the display effect.

In an implementation, as shown in FIG. 2, the first pixel definition layer 3 has a first surface 303 facing the base substrate 1 and a second surface 304 facing away from the base substrate 1. The first side surface 302 connects the first surface 303 and the second surface 304. The width of the first opening region 301 on the first surface 303 is d1. The width of the first opening region 301 on the second surface 304 is d2. A half d2/2 of the width d2 of the first opening region 301 on the second surface 304 is equal to the radius r of the first side surface 302.

In an implementation, when manufacturing the first pixel definition layer, a whole first pixel definition layer may be formed first, and then a patterning process such as exposure and development may be used to form a pattern of a plurality of first opening regions. For example, the pattern of a plurality of first opening regions may be formed in multiple exposure processes so that the first side surface is a portion of a spherical surface. In the first exposure process, a first opening region with a rectangular cross section along a direction perpendicular to the base substrate can be formed. That is, after the one-side exposure process, the side surface of the first pixel definition layer surrounding the first opening region is perpendicular to the base substrate. In the second exposure process, a first side surface being a portion of a spherical surface having a radius of r=d2/2 is formed.

In some embodiments, as shown in FIG. 2, the width d1 of the first opening region 301 on the first surface 303 and the width d2 of the first opening region 301 on the second surface 304 in the first direction X or in the second direction Y, and the thickness h1 of the first pixel definition layer 3 in the direction perpendicular to the base substrate 1 satisfy:

$$\frac{d 2}{2} = \sqrt{{( \frac{d 1}{2} )}^{2} + h {1}^{2}} .$$

That is, the radius r of the sphere satisfies:

$$r = \frac{d 2}{2} = \sqrt{{( \frac{d 1}{2} )}^{2} + h {1}^{2}} .$$

It should be noted that FIG. 2 only shows d1 and d2 in the first direction X.

In some embodiments, a thickness h1 of the first pixel definition layer in a direction perpendicular to the base substrate is greater than or equal to 10 μm and less than or equal to 20 μm.

In an implementation, in a direction perpendicular to the base substrate, the thickness of the quantum dot pattern is equal to the thickness of the first pixel definition layer. That is, the thickness of the quantum dot pattern is also h1. When h1 is greater than or equal to 10 μm and less than or equal to 20 μm, as shown in FIG. 1, the quantum dot pattern has a higher conversion rate.

Furthermore, in a direction perpendicular to the base substrate, a thickness h1 of the first pixel definition layer is greater than or equal to 10 μm and less than or equal to 15 μm.

It should be noted that, as shown in FIG. 1, when the film thickness and the thickness of the quantum dot pattern in the direction perpendicular to the base substrate are both less than or equal to 15 μm, the conversion rate of the quantum dot pattern increases with the increase of the film thickness. When the thickness of the quantum dot pattern is greater than 15 μm, the conversion rate of the quantum dot pattern decreases with the increase of the film thickness. That is, when the thickness of the quantum dot pattern is greater than 15 μm, increasing the thickness of the first pixel definition layer and the thickness of the quantum dot pattern will not increase the conversion rate of the quantum dot pattern. h1 is greater than or equal to 10 μm and less than or equal to 15 μm, which can ensure that the quantum dot pattern has a high conversion rate while avoiding excessive increase in the thickness of the first pixel definition layer and the quantum dot pattern, thereby avoiding excessive increase in the total thickness of the display panel.

In an implementation, in the first direction X or in the second direction Y, d1 is, for example, greater than or equal to 4 μm and less than or equal to 120 μm.

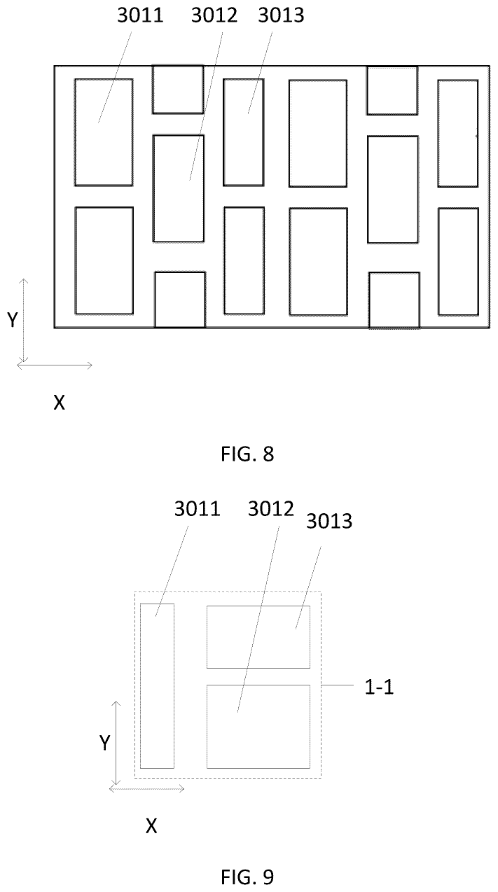

In some embodiments, the shape of the orthographic projection of the first opening region 301 on the base substrate is shown in FIGS. 8 to 21.

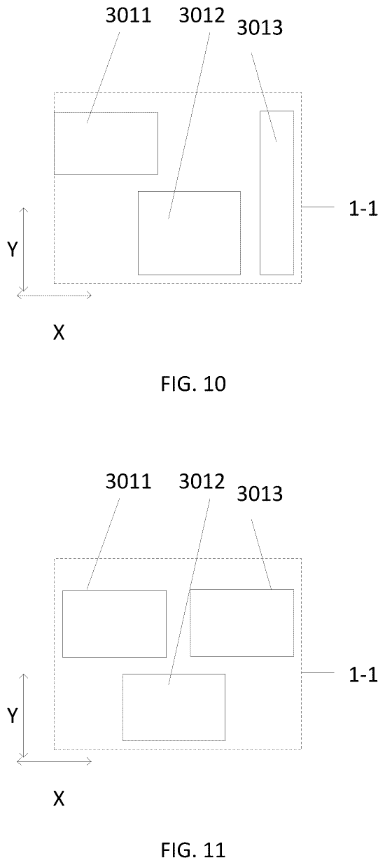

For example, as shown in FIGS. 8 to 11, the plurality of first opening regions 301 each includes a first sub-pixel opening region 3011, a second sub-pixel opening region 3012, and a third sub-pixel opening region 3013. The first sub-pixel opening region 3011, the second sub-pixel opening region 3012, and the third sub-pixel opening region 3013 correspond to different sub-pixel regions respectively. As shown in FIG. 8, the second sub-pixel opening region 3012 is staggered with the first sub-pixel opening region 3011. The second sub-pixel opening region 3012 is staggered with the third sub-pixel opening region 3013. As shown in FIG. 9, in the first sub-pixel opening region 3011, the second sub-pixel opening region 3012 and the third sub-pixel opening region 3013 corresponding to a pixel 1-1, the first sub-pixel opening region 3011 is adjacent to both the second sub-pixel opening region 3012 and the third sub-pixel opening region 3013 in the first direction X. The outline of the arrangement of the first sub-pixel opening region 3011, the second sub-pixel opening region 3012 and the third sub-pixel opening region 3013 corresponding to the pixel 1-1 is a rectangle. As shown in FIG. 10, in the first direction X, the projection of the first sub-pixel opening region 3011 and the projection of the second sub-pixel opening region 3012 each overlaps with the projection of the third sub-pixel opening region 3013, and the projection of the first sub-pixel opening region 3011 and the projection of the third sub-pixel opening region 3013 have a non-overlapping region. In the second direction Y, the projection of the first sub-pixel opening region 3011 and the projection of the second sub-pixel opening region 3012 have an overlapping area. As shown in FIG. 11, the first sub-pixel opening region 3011, the second sub-pixel opening region 3012, and the third sub-pixel opening region 3013 corresponding to a pixel 1-1 are arranged in two rows. Lines connecting centers of the first sub-pixel opening region 3011, the second sub-pixel opening region 3012 and the third sub-pixel opening region 3013 form a triangle.

In an implementation, as shown in FIGS. 8, 9 and 10, the areas of the first sub-pixel opening region 3011, the second sub-pixel opening region 3012 and the third sub-pixel opening region 3013 are not exactly the same. Alternatively, as shown in FIG. 11, the areas of the first sub-pixel opening region 3011, the second sub-pixel opening region 3012 and the third sub-pixel opening region 3013 are exactly the same.

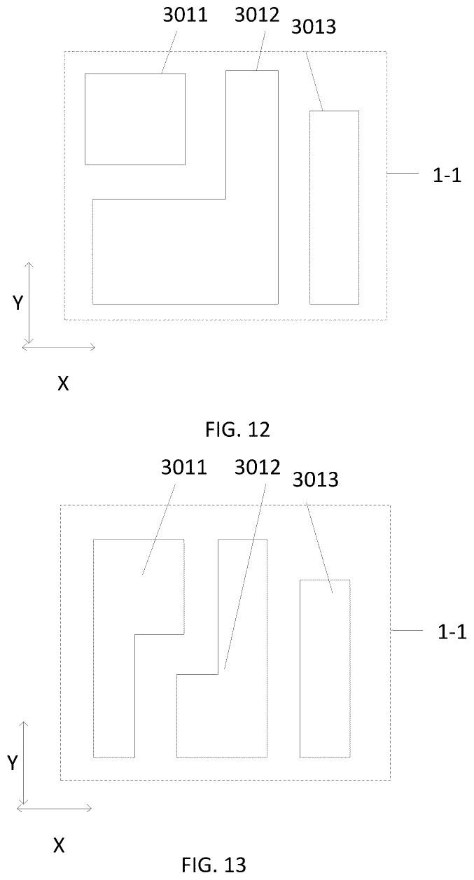

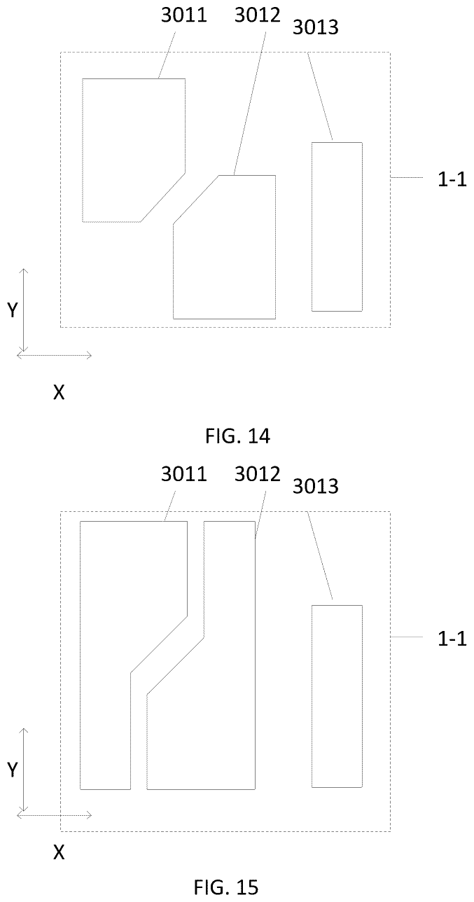

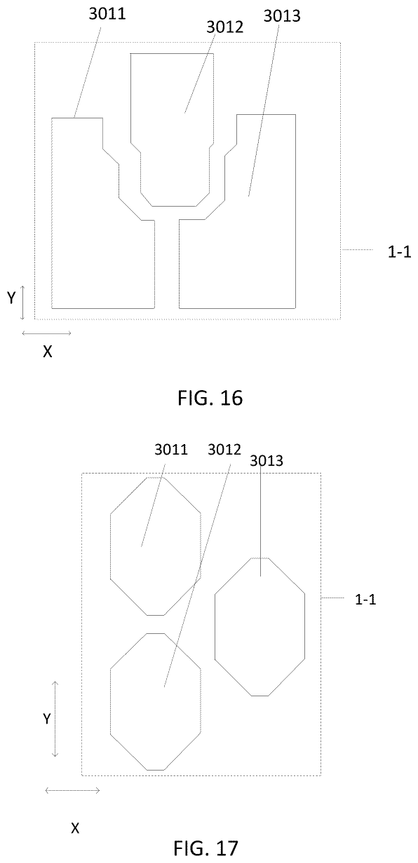

Alternatively, in an implementation, as shown in FIGS. 12 to 16, at least part of the first opening region may also be in other shapes. As shown in FIG. 12, the first sub-pixel opening region 3011 and the third sub-pixel opening region 3013 are rectangular in shape, and the second sub-pixel opening region 3012 is L-shaped. As shown in FIG. 13, the first sub-pixel opening region 3011 and the second sub-pixel opening region 3012 are L-shaped, and the third sub-pixel opening region 3013 is rectangular in shape. As shown in FIGS. 14 and 15, the first sub-pixel opening region 3011 and the second sub-pixel opening region 3012 are pentagonal in shape, and the third sub-pixel opening region 3013 is rectangular in shape. As shown in FIG. 16, the first sub-pixel opening region 3011, the second sub-pixel opening region 3012 and the third sub-pixel opening region 3013 are all irregular polygons.

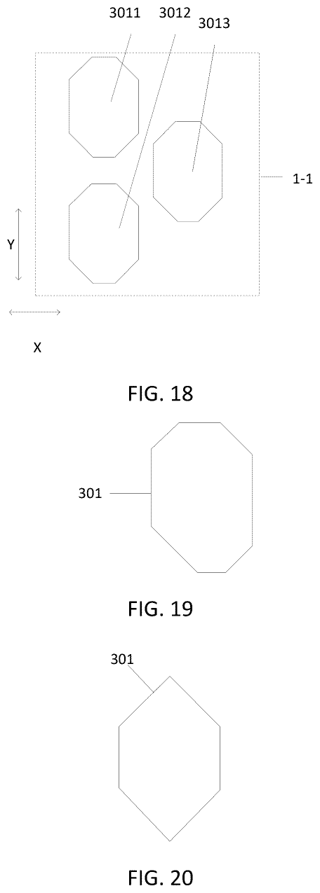

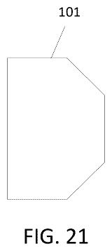

Alternatively, in an implementation, as shown in FIGS. 17 to 21, the first sub-pixel opening region 3011, the second sub-pixel opening region 3012, and the third sub-pixel opening region 3013 are all non-rectangular. As shown in FIGS. 17 and 18, the first sub-pixel opening region 3011, the second sub-pixel opening region 3012 and the third sub-pixel opening region 3013 are all octagons. The first sub-pixel opening region 3011, the second sub-pixel opening region 3012 and the third sub-pixel opening region 3013 corresponding to one pixel 1-1 are arranged in two columns. The lines connecting centers of the first sub-pixel opening region 3011, the second sub-pixel opening region 3012 and the third sub-pixel opening region 3013 form a triangle. The first opening region 301 shown in FIG. 19 is an asymmetric octagon. The first opening region 301 shown in FIG. 20 is a hexagon. The first opening region 301 shown in FIG. 21 is a heptagon.

In some embodiments, as shown in FIG. 2, in the first direction X or in the second direction Y, the width d1 of the first opening region 301 on the first surface 303, the width d2 of the first opening region 301 on the second surface 304, and the width L1 of the first pixel definition layer 3 on the first surface 303 satisfy:

$$\frac{d 2}{2} \leq \frac{d 1}{2} + \frac{L 1}{3} .$$

It should be noted that, as shown in FIG. 2, since the cross-sectional areas of the first opening region 301 parallel to the plane where the base substrate 1 is located gradually increase in the direction pointing from the base substrate 1 to the first pixel definition layer 3 the width of the first pixel definition layer 3 in the first direction X or in the second direction Y gradually decreases, and the width of the first pixel definition layer 3 on the first surface 303 is L1.

In an implementation, in order to ensure that the sub-pixel has a larger aperture ratio, L1 is greater than or equal to 20 μm and less than or equal to 40 μm.

In some embodiments, the maximum width L1 of the first pixel definition layer 3 in the first direction X or in the second direction Y and the thickness h1 of the first pixel definition layer 3 in the direction perpendicular to the base substrate 1 satisfy:

$$\frac{1}{2} \leq \frac{L 1}{h 1} \leq 1 .$$

In some embodiments, in the first direction X or in the second direction Y, the width d1 of the first opening region 301 on the first surface 303 and the thickness h1 of the first pixel definition layer 3 in a direction perpendicular to the base substrate 1 satisfy:

$$\frac{1}{12} \leq \frac{h 1}{d 1} \leq \frac{1}{4} .$$

It should be noted that, as shown in FIG. 2, the larger the angle a1 is, the greater the curvature of the first side surface 302 is, so that more light 11 incident on the first side surface 302 can be emitted toward the front side of the display panel.

In the display panel provided by the embodiments of the present disclosure,

$$\frac{1}{12} \leq \frac{h 1}{d 1} \leq \frac{1}{4} .$$

### That is,

$$\frac{1}{6} \leq \frac{h 1}{\frac{d}{2}} \leq \frac{1}{2} , 9. {5}^{∘} \leq a 1 \leq 26 . {6}^{∘} .$$

While ensuring that the sub-pixel has a large aperture ratio, the angle a1 can be made as large as possible and the curvature of the first side surface can be increased so that more light incident on the first side surface is emitted toward the front side of the display panel, thereby improving the front light extraction efficiency of the display panel.

In an implementation, when the light-emitting devices are blue light-emitting devices and the first side surface of the first pixel definition layer is a part of a spherical surface, the light reaching the first side surface is reflected and the light path is changed to be emitted in a direction perpendicular to or nearly perpendicular to the base substrate, thereby improving the light extraction efficiency at the front side of the display panel. Compared with the display panel provided by the prior art as shown in FIG. 5, the display panel provided by the embodiments of the present disclosure can improve the front light extraction efficiency corresponding to the red sub-pixel region and the green sub-pixel region by about 10%, and the front light extraction efficiency corresponding to the blue sub-pixel region by about 5%.

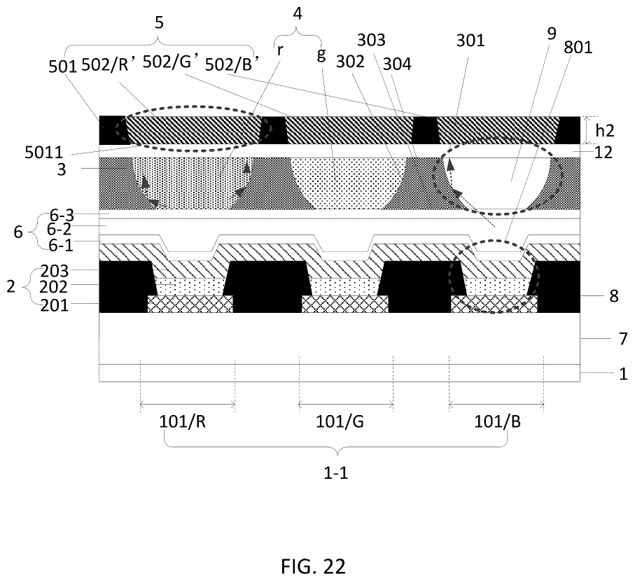

In some embodiments, as shown in FIG. 22, the display panel further includes a color filter layer 5.

The color filter layer 5 is located on the side of the quantum dot pattern 4 facing away from the base substrate 1.

In some embodiments, as shown in FIG. 22, the color filter layer 5 includes: a light shielding layer 501 and a plurality of color resists 502.

The light shielding layer 501 has a plurality of second opening regions 5011. The color resist 502 is located in the second opening regions 5011. The second opening regions 5011 correspond one-to-one to the sub-pixel regions 101.

The orthographic projection of the second opening region 5011 on the base substrate 1 overlaps with the orthographic projection of the first opening region 301 on the base substrate 1.

In some embodiments, as shown in FIG. 22, the plurality of color resists 33 include: red color resists R′ corresponding one-to-one to the red sub-pixel regions R, green color resists G′ corresponding one-to-one to the green sub-pixel regions G, and blue color resists B′ corresponding one-to-one to the blue sub-pixel regions B.

In an implementation, the color resist includes a filter material, for example, a dye corresponding to the color of the sub-pixel.

It should be noted that after the blue light emitted by the light-emitting device reaches the red light quantum dot pattern or the green light quantum dot pattern, it may not be completely absorbed and may be emitted from the quantum dot pattern. That is, the light emitted by the red light quantum dot pattern or the green light quantum dot pattern may contain blue light, which will cause the color purity of the red sub-pixel region and the green sub-pixel region to be reduced.

The display panel provided by the embodiments of the present disclosure has a color filter layer including color resists disposed on the side of the quantum dot pattern away from the base substrate. The color resists can filter the blue light emitted by the quantum dot pattern to improve the color purity.

It should be noted that in the related art, since the light conversion efficiency of the quantum dot pattern is not high, a thicker color resist layer, namely a color filter layer, needs to be provided to ensure the filtering effect of the red color resist and the green color resist on the blue light. In the related art, the thickness of the color filter layer is greater than or equal to 2 μm and less than or equal to 6 μm. The display panel provided by the embodiments of the present disclosure has a first pixel definition layer, and the light reaching the first side surface of the first pixel definition layer will be reflected. Therefore, the blue light that is not absorbed by the quantum dot pattern is reflected after reaching the first side surface, thereby changing the light path. In this way, part of the reflected blue light returns to the quantum dot pattern to excite the quantum dot particles in the quantum dot pattern to emit green light or red light. That is, compared with the prior art, the display panel provided by the embodiments of the present disclosure can reduce the blue light emitted from the quantum dot pattern, and therefore, the thickness of the color filter layer can be reduced, thereby reducing the cost.

In some embodiments, as shown in FIG. 22, a thickness h2 of the color filter layer 5 in a direction perpendicular to the base substrate 1 is greater than or equal to 1 μm and less than or equal to 4 μm.

That is, compared with the prior art, the thickness of the color filter layer of the display panel provided by the embodiments of the present disclosure can be reduced by ⅓ to half.

In some embodiments, as shown in FIG. 22, the display panel further includes: a quantum dot encapsulation layer 12 between the quantum dot pattern 4 and the color filter layer 5.

In some embodiments, the light-emitting devices are electroluminescent devices. The electroluminescent devices are, for example, organic light emitting diode devices. Alternatively, the electroluminescent devices may also be other light-emitting devices such as Micro LED and Mini LED.

Next, taking light-emitting devices being OLED light-emitting devices as an example for explanation.

In some embodiments, as shown in FIG. 2 and FIG. 22, the display panel further includes: an encapsulation layer 6, a driving circuit layer 7, and a second pixel definition layer 8.

The encapsulation layer 6 is between the first pixel definition layer 3 and the light-emitting device 2.

The driving circuit layer 7 is between the base substrate 1 and the light-emitting device 2.

The second pixel definition layer 8 is between the driving circuit layer 7 and the first pixel definition layer 3. The second pixel definition layer 8 includes third opening regions 801 corresponding one-to-one to the sub-pixel regions 101.

In some embodiments, as shown in FIGS. 2 and 22, the light-emitting device 2 includes an anode 201, a light-emitting functional layer 202, and a cathode 203 which are stacked in sequence in the third opening region 801. The anode 201 is between the second pixel definition layer 8 and the driving circuit layer 7. The second pixel definition layer 8 covers the edge of the anode 201. The cathodes 203 corresponding to multiple sub-pixel regions 101 are integrally connected.

In some embodiments, the display panel may further include a light extraction layer between the cathode and the encapsulation layer.

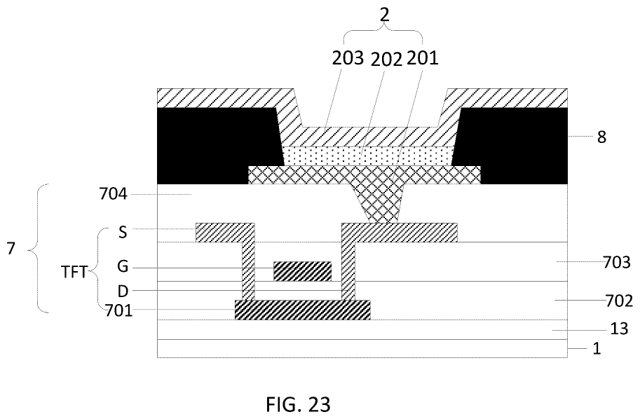

In an implementation, the driving circuit layer includes a plurality of pixel driving circuits arranged in an array. The pixel driving circuit is used to drive the light-emitting device to emit light. As shown in FIG. 23, the pixel driving circuit includes a thin film transistor TFT and a storage capacitor (not shown). FIG. 23 only shows one thin film transistor TFT connected to the light-emitting device 2. Of course, the pixel driving circuit can also include more thin film transistors. The thin film transistor TFT includes: an active layer 701, a gate G, a source S and a drain D. As shown in FIG. 23, the display panel also includes: a buffer layer 13 between the base substrate 1 and the active layer 701. The driving circuit layer 7 also includes: a first gate insulating layer 702 between the active layer 701 and the gate G, an interlayer insulating layer 703 between the first gate insulating layer 702 and the source S and the drain D, and a first planarization layer 704 located between the light-emitting device 2 and the source S and the drain D. The anode 203 is connected to the drain D through a via hole penetrating the first planarization layer 704. FIG. 23 illustrates a top-gate structure of a thin film transistor TFT. Of course, the thin film transistor TFT may also be a bottom-gate structure or other structures. When the thin film transistor is a bottom-gate structure, the active layer is located on the side of the gate away from the base substrate, and the driving circuit layer also includes: a first gate insulating layer between the active layer and the gate, and a first planarization layer between the light-emitting device and the source and drain.

In an implementation, the light-emitting functional layer includes an organic light-emitting layer, and may also include an electron injection layer, an electron transport layer, a hole transport layer, a hole injection layer, and the like.

In an implementation, when all the light-emitting devices are blue light-emitting devices, the organic light-emitting layers corresponding to respective sub-pixel regions all emit blue light. The light-emitting spectra of the organic light-emitting layers corresponding to respective sub-pixel regions may be the same or different.

In some embodiments, as shown in FIG. 2 and FIG. 22, the display panel includes a multi-layer encapsulation layer 6.

The multi-layer encapsulation layer 6 includes: a first encapsulation layer 6-1, a second encapsulation layer 6-2, and a third encapsulation layer 6-3 which are sequentially stacked on the side of the light-emitting device 2 away from the base substrate 1.

In an implementation, the first encapsulation layer 6-1, the second encapsulation layer 6-2, and the third encapsulation layer 6-3 in FIG. 2 and FIG. 22 are all single-layer films.

In an implementation, the first encapsulation layer 6-1 and the third encapsulation layer 6-3 in FIG. 2 and FIG. 22 are, for example, inorganic encapsulation layers, and the second encapsulation layer 6-2 is, for example, an organic encapsulation layer.

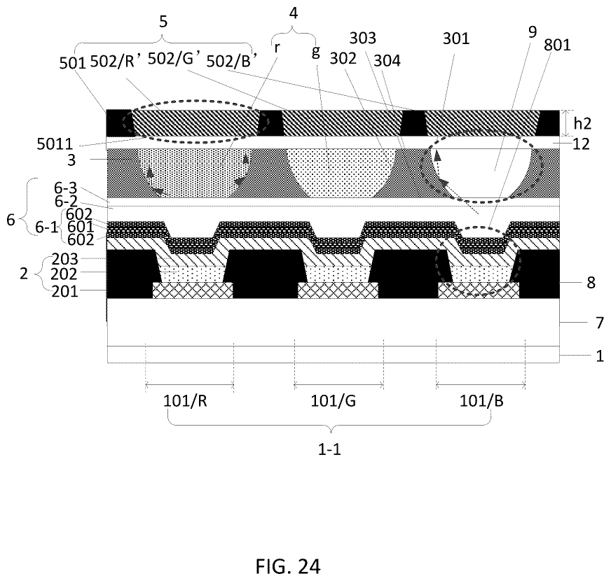

Alternatively, in some embodiments, as shown in FIGS. 24 to 26, at least one encapsulation layer 6 is a composite structure including multiple film layers.

In some embodiments, as shown in FIGS. 24 to 26, the display panel includes a multi-layer encapsulation layer 6.

At least one encapsulation layer 6 in the multi-layer encapsulation layer 6 includes: n low-refractive index encapsulation sub-layers 601 and n+1 high-refractive index encapsulation sub-layers 602. Here n is an integer greater than or equal to 1. The refractive index of the high-refractive index encapsulation sub-layer 602 is greater than the refractive index of the low-refractive index encapsulation sub-layer 601.

The low-refractive index encapsulation sub-layers 601 and the high-refractive index encapsulation sub-layers 602 are arranged alternately.

In an implementation, the encapsulation layer includes: n low-refractive index encapsulation sub-layers and n+1 high-refractive index encapsulation sub-layers. That is, the encapsulation layer includes at least 1 low-refractive index encapsulation sub-layer and 2 high-refractive index encapsulation sub-layers.

In an implementation, as shown in FIGS. 24 to 26, when the encapsulation layer 6 includes: n layers of low-refractive index encapsulation sub-layers 601 and n+1 layers of high-refractive index encapsulation sub-layers 602, the encapsulation sub-layer on the side closest to the base substrate 1 and the encapsulation sub-layer on the side farthest from the base substrate 1 in the encapsulation layer 6 are both high-refractive index encapsulation sub-layers 602.

In the display panel provided by the embodiments of the present disclosure, a portion of the light emitted by the quantum dot pattern will be emitted toward one side of the encapsulation layer. When the light propagates to the encapsulation layer, since at least one of the multiple encapsulation layers includes alternating low-refractive index encapsulation sub-layers and high-refractive index encapsulation sub-layers, and the refractive index of the low-refractive index encapsulation sub-layer is less than the refractive index of the high-refractive index encapsulation sub-layer, the interference of the reflected light reflected at the interface between the low-refractive index encapsulation sub-layer and the high-refractive index encapsulation sub-layer increases the light reflectivity within a specific wavelength range. Therefore, at the interface between the low-refractive index encapsulation sub-layer and the high-refractive index encapsulation sub-layer, the light emitted by the quantum dot pattern and propagating to the base substrate can be reflected back to the front side and then emitted, which can improve the light utilization rate and thereby improve the brightness conversion rate of the quantum dot pattern.

In some embodiments, the high-refractive index encapsulation sub-layer includes an inorganic material.

In some embodiments, the high-refractive index encapsulation sub-layer includes one or a combination of the following: silicon nitride, silicon oxide, or silicon oxynitride.

In some embodiments, the low-refractive index encapsulation sub-layer includes an organic material.

In some embodiments, the low-refractive index encapsulation sub-layer includes one or a combination of the following: acrylic resin, epoxy resin, phenolic resin, polyamide resin, polyimide resin, unsaturated polyester resin, polyphenylene resin, polyphenylene sulfide resin, benzocyclobutene.

In an implementation, the thicknesses and refractive indices of the low-refractive index encapsulation sub-layer and the high-refractive index encapsulation sub-layer can be adjusted to increase the light reflectivity or transmittance within a specific wavelength range. For example, for an encapsulation layer including a low-refractive index encapsulation sub-layer and a high-refractive index encapsulation sub-layer, the encapsulation layer can be set to have a higher reflectivity for red light and green light, so that the red light or green light emitted by the quantum dot pattern and propagating toward the base substrate can be reflected back to the front side and then emitted, which can improve the light utilization rate and thereby improve the brightness conversion rate of the quantum dot pattern.

In some embodiments, the high-refractive index encapsulation sub-layer has a refractive index greater than or equal to 1.6 and less than or equal to 1.85.

In some embodiments, the thickness of the high-refractive index encapsulation sub-layer is greater than or equal to 0.2 μm and less than or equal to 1.0 μm.

In some embodiments, the refractive index of the low-refractive index encapsulation sub-layer is greater than or equal to 1.4 and less than or equal to 1.5.

In some embodiments, the thickness of the low-refractive index encapsulation sub-layer is greater than or equal to 0.4 μm and less than or equal to 1.0 μm.

In an implementation, for an encapsulation layer including a low-refractive index encapsulation sub-layer and high-refractive index encapsulation sub-layers, the materials of the high-refractive index encapsulation sub-layers in different layers may be the same or different, the refractive indices of the high-refractive index encapsulation sub-layers in different layers may be the same or different, and the thicknesses of the high-refractive index encapsulation sub-layers in different layers may be the same or different. If the encapsulation layer includes multiple low-refractive index encapsulation sub-layers, the materials of the low-refractive index encapsulation sub-layers in different layers may be the same or different, the refractive indices of the low-refractive index encapsulation sub-layers in different layers may be the same or different, and the thicknesses of the low-refractive index encapsulation sub-layers in different layers may be the same or different.

In an implementation, as shown in FIGS. 24 to 26, the multi-layer encapsulation layer 6 includes: a first encapsulation layer 6-1, a second encapsulation layer 6-2, and a third encapsulation layer 6-3 which are sequentially stacked on the side of the light-emitting device 2 away from the base substrate 1.

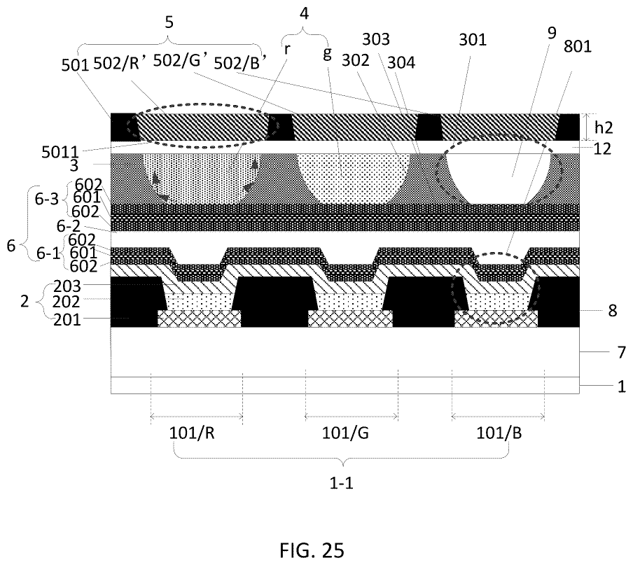

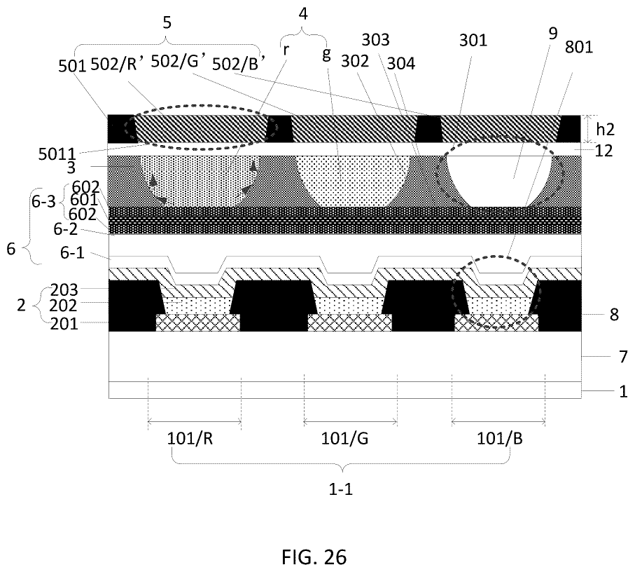

In an implementation, as shown in FIGS. 24 to 26, the first encapsulation layer 6-1 and/or the third encapsulation layer 6-3 includes a low-refractive index encapsulation sub-layer 601 and a high-refractive index encapsulation sub-layer 602. That is, as shown in FIG. 24, only the first encapsulation layer 6-1 includes a low-refractive index encapsulation sub-layer 601 and high-refractive index encapsulation sub-layers 602. Alternatively, as shown in FIG. 25, the first encapsulation layer 6-1 and the third encapsulation layer 6-3 both include a low-refractive index encapsulation sub-layer 601 and high-refractive index encapsulation sub-layers 602. Alternatively, as shown in FIG. 26, only the third encapsulation layer 6-3 includes a low-refractive index encapsulation sub-layer 601 and high-refractive index encapsulation sub-layers 602.

In an implementation, the second encapsulation layer is, for example, an organic encapsulation layer. As shown in FIG. 24, when only the first encapsulation layer 6-1 includes a low-refractive index encapsulation sub-layer 601 and high-refractive index encapsulation sub-layers 602, the third encapsulation layer 6-3 is an inorganic encapsulation layer. As shown in FIG. 26, when only the third encapsulation layer 6-3 includes a low-refractive index encapsulation sub-layer 601 and high-refractive index encapsulation sub-layers 602, the first encapsulation layer 6-1 is an inorganic encapsulation layer.

It should be noted that the second encapsulation layer, i.e., the organic encapsulation layer, is used for planarization, and thus its thickness is relatively thick, usually greater than or equal to 8 micrometers and less than or equal to 12 micrometers. When the encapsulation layer closest to the base substrate among the multi-layer encapsulation layers, i.e., the first encapsulation layer, includes a low-refractive index encapsulation sub-layer and high-refractive index encapsulation sub-layers, the light reflected at the interface between the low-refractive index encapsulation sub-layer and the high-refractive index encapsulation sub-layer must pass through the second encapsulation layer before being emitted, resulting in a loss of transmittance. In some embodiments, as shown in FIGS. 25 and 26, the encapsulation layer 6 closest to the quantum dot pattern 4 includes a low-refractive index encapsulation sub-layer 601 and high-refractive index encapsulation sub-layers 602, that is, the third encapsulation layer 6-3 includes a low-refractive index encapsulation sub-layer 601 and high-refractive index encapsulation sub-layers 602, so that light reflected at the interface between the low-refractive index encapsulation sub-layer and the high-refractive index encapsulation sub-layer does not need to pass through the second encapsulation layer, avoiding the loss of transmittance, which is more conducive to improving light utilization and improving the brightness conversion rate of the quantum dot pattern.

In some embodiments, as shown in FIGS. 24 to 26, n=1, that is, the encapsulation layer includes one low-refractive index encapsulation sub-layer 601 and two high-refractive index encapsulation sub-layers 602. The one low-refractive index encapsulation sub-layer 601 is located between the two high-refractive index encapsulation sub-layers 602. The encapsulation layer 6 is a composite structure of three encapsulation sub-layers.

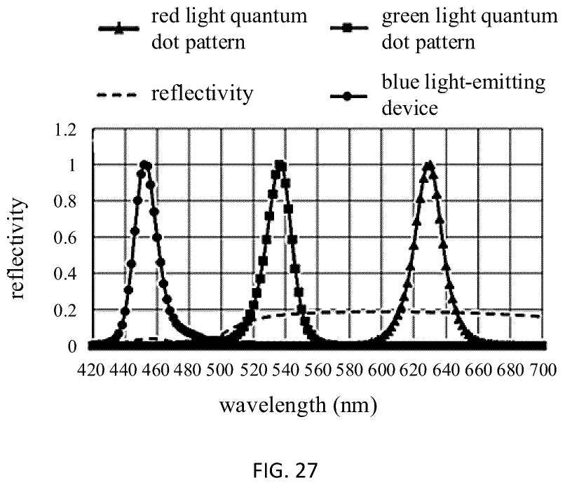

Next, taking the example of only the third encapsulation layer including 1 low-refractive index encapsulation sub-layer and 2 high-refractive index encapsulation sub-layers, the reflectivity simulation results of the third encapsulation layer are introduced. The reflectivity curves of the encapsulation layer for different bands are shown in FIG. 27. The reflectivity of the encapsulation layer for the green light band (wavelength range of 520 nm~570 nm) and the red light band (wavelength range of 600 nm~690 nm) is close to 20%, that is, about 20% of the green light and red light in the quantum dot pattern incident on the interface of the third encapsulation layer can be reflected, and the light path is changed, so that it is emitted from the front side, thereby increasing the overall front light extraction efficiency of the display panel. In FIG. 27, the reflectivity of the third encapsulation layer for the blue light band (wavelength range of 400 nm to 480 nm) is ≤2%, which can be ignored, and thus will not affect the blue light emitted by the light-emitting device passing through the encapsulation layer. It can be seen that setting the encapsulation layer as a composite structure of a low-refractive index encapsulation sub-layer and high-refractive index encapsulation sub-layers can effectively improve the reflectivity of red light and green light, thereby improving the light utilization rate to enhance the brightness conversion rate of the quantum dot pattern. When the third encapsulation layer includes one low-refractive index encapsulation sub-layer and two high-refractive index encapsulation sub-layers, the front light extraction efficiencies of the red sub-pixel region and the green sub-pixel region of the display panel are expected to be increased by 12% and 15% respectively.

It should be noted that when the encapsulation layer includes alternating low-refractive index encapsulation sub-layers and high-refractive index encapsulation sub-layers, the greater the difference in refractive indices between the low-refractive index encapsulation sub-layer and the high-refractive index encapsulation sub-layer, the stronger the total reflection effect at the interface between the two, which is more conducive to improving the reflectivity.

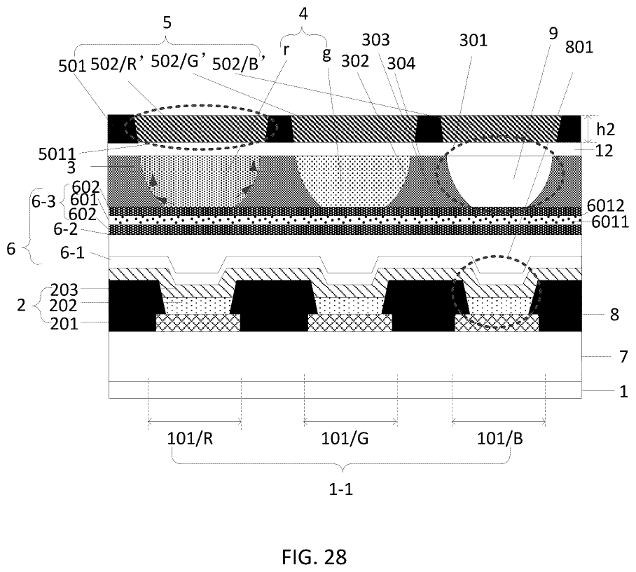

In some embodiments, as shown in FIG. 28, at least one low-refractive index encapsulation sub-layer 601 further includes a plurality of scattering particles 6011.

That is, as shown in FIG. 28, the low-refractive index encapsulation sub-layer 601 includes a base material 6012 and a plurality of scattering particles 6011.

In the display panel provided by the embodiments of the present disclosure, the low-refractive index encapsulation sub-layer also includes a plurality of scattering particles, which can reduce the refractive index of the overall film layer, making it easier to achieve that the refractive index of the low-refractive index encapsulation sub-layer is lower than the refractive index of the high-refractive index encapsulation sub-layer, further increasing the refractive index difference between the low-refractive index encapsulation sub-layer and the high-refractive index encapsulation sub-layer, and being more conducive to improving the total reflection effect of the interface between the two, and more conducive to improving the reflectivity.

In an implementation, the base material is an organic material, and the base material includes one or a combination of the following: acrylic resin, epoxy resin, phenolic resin, polyamide resin, polyimide resin, unsaturated polyester resin, polyphenylene resin, polyphenylene sulfide resin, and benzocyclobutene.

In some embodiments, the plurality of scattering particles include one or a combination of the following: zinc oxide particles, titanium dioxide particles, hollow silica particles, non-hollow silica particles, nanosilicate particles, porogen particles.

In some embodiments, the refractive index of the low-refractive index encapsulation sub-layer is greater than or equal to 1.1 and less than or equal to 1.4.

In some embodiments, the thickness of the low-refractive index encapsulation sub-layer is greater than or equal to 0.2 μm and less than or equal to 0.4 μm.

In some embodiments, the mass percentage of the scattering particles is greater than or equal to 5% and less than or equal to 10%.

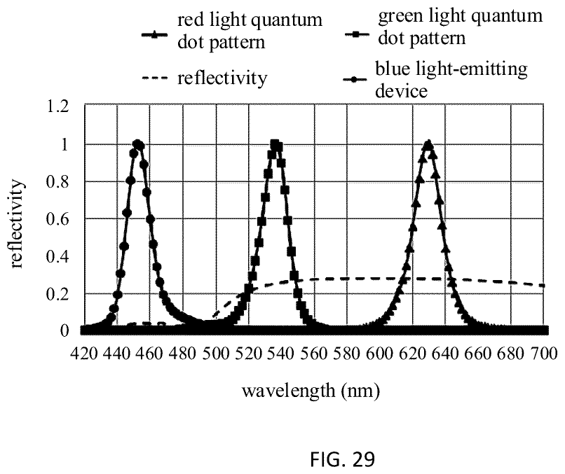

Next, taking the example that only the third encapsulation layer includes 1 low-refractive index encapsulation sub-layer and 2 high-refractive index encapsulation sub-layers, and the low-refractive index encapsulation sub-layer includes scattering particles, the reflectivity simulation results of the third encapsulation layer are introduced. The reflectivity curves of the encapsulation layer for different bands are shown in FIG. 29. The reflectivity of the encapsulation layer for the green light band (wavelength range is 520 nm~570 nm) and the red light band (wavelength range is 600 nm~690 nm) is close to 25%, that is, about 25% of the green light and red light in the quantum dot pattern incident on the interface of the third encapsulation layer can be reflected, and the light path changes, so that it is emitted from the front side, thereby increasing the overall front light extraction efficiency of the display panel. In FIG. 29, the reflectivity of the third encapsulation layer for the blue light band (wavelength range of 400 nm to 480 nm) is ≤2%, which can be ignored, and thus will not affect the blue light emitted by the light-emitting device passing through the encapsulation layer. This shows that adding scattering particles to the low-refractive index encapsulation sub-layer can effectively improve the reflectivity of red and green light, thereby improving light utilization to enhance the brightness conversion rate of the quantum dot pattern. When the third encapsulation layer includes one low-refractive index encapsulation sub-layer and two high-refractive index encapsulation sub-layers, and the low-refractive index encapsulation sub-layer includes scattering particles, the front light extraction efficiencies of the red sub-pixel region and the green sub-pixel region of the display panel are expected to increase by 13% and 16% respectively.

It should be noted that FIGS. 24 to 26 and FIG. 28 illustrate the example in which the encapsulation layer includes one low-refractive index encapsulation sub-layer and two high-refractive index encapsulation sub-layers. Of course, in an implementation, the encapsulation layer can also include more low-refractive index encapsulation sub-layers and more high-refractive index encapsulation sub-layers.

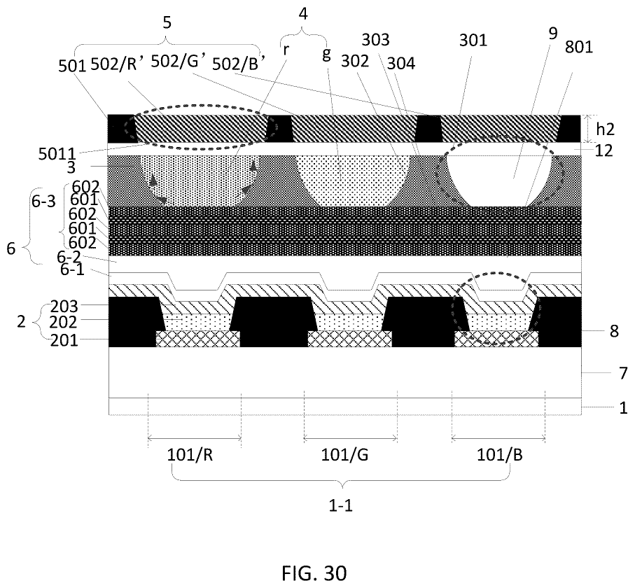

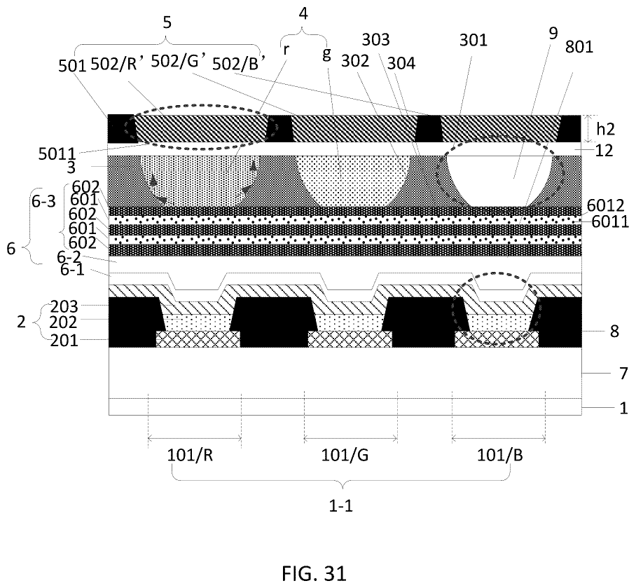

In some embodiments, as shown in FIG. 30 and FIG. 31, n=2. That is, the encapsulation layer 6 includes two low-refractive index encapsulation sub-layers and three high-refractive index encapsulation sub-layers, and the encapsulation layer 6 is a composite structure of five encapsulation sub-layers.

It should be noted that, in FIGS. 30 and 31, only the third encapsulation sub-layer 6-3 includes two low-refractive index encapsulation sub-layers 601 and three high-refractive index encapsulation sub-layers 602. In FIG. 30, the low-refractive index encapsulation sub-layer 601 does not include scattering particles. In an implementation, when the encapsulation layer includes a plurality of low-refractive index encapsulation sub-layers, a plurality of scattering particles may be added to at least one of the low-refractive index encapsulation sub-layers. For example, as shown in FIG. 31, both of the two low-refractive index encapsulation sub-layers 601 include scattering particles.

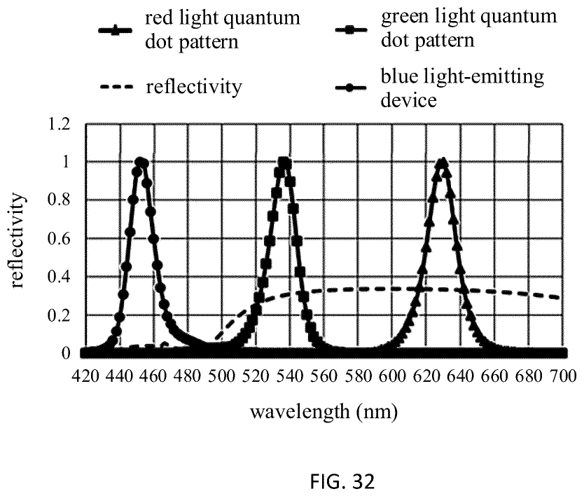

Next, taking the example that only the third encapsulation layer includes 2 low-refractive index encapsulation sub-layers and 3 high-refractive index encapsulation sub-layers, and the low-refractive index encapsulation sub-layer includes scattering particles, the reflectivity simulation results of the third encapsulation layer are introduced. The reflectivity curves of the encapsulation layer for different bands are shown in FIG. 32. The reflectivity of the encapsulation layer for the green light band (wavelength range is 520 nm~570 nm) and the red light band (wavelength range is 600 nm~690 nm) is close to 32%, that is, about 32% of the green light and red light in the quantum dot pattern incident on the interface of the third encapsulation layer can be reflected, and the light path changes, so that it is emitted from the front side, thereby increasing the overall front light extraction efficiency of the display panel. In FIG. 32, the reflectivity of the third encapsulation layer for the blue light band (wavelength range of 400 nm to 480 nm) is ≤2%, which can be ignored, and thus will not affect the blue light emitted by the light-emitting device passing through the encapsulation layer. It can be seen that increasing the number of encapsulation sub-layers to 5 layers can further improve the reflectivity of red light and green light, thereby improving the light utilization efficiency to enhance the brightness conversion rate of the quantum dot pattern. When the third encapsulation layer includes 2 low-refractive index encapsulation sub-layers and 3 high-refractive index encapsulation sub-layers, and the low-refractive index encapsulation sub-layer includes scattering particles, the front light output efficiencies of the red sub-pixel region and the green sub-pixel region of the display panel are expected to increase by 15% and 18% respectively.

It should be noted that if the number of low-refractive index encapsulation sub-layers and high-refractive index encapsulation sub-layers included in the encapsulation layer continues to increase, it may lead to optical waveguides between the low-refractive index encapsulation sub-layers and the high-refractive index encapsulation sub-layers in the encapsulation layer, and the thickness of the encapsulation layer may be excessive and affect the transmittance, thereby affecting the overall gain of the display panel. In an implementation, the number of low-refractive index encapsulation sub-layers and high-refractive index encapsulation sub-layers included in the encapsulation layer may be selected by comprehensively considering factors such as the reflectivity and transmittance of the encapsulation layer.

A display device provided by embodiments of the present disclosure includes the display panel provided by embodiments of the present disclosure.

The display device provided in the embodiments of the present disclosure is any product or component with a display function, such as a mobile phone, a tablet computer, a television, a monitor, a laptop computer, a digital photo frame, and a navigator. Other essential components of the display device should be understood by those skilled in the art and will not be described in detail herein and should not be construed as limiting the present disclosure. The implementation of the display device may refer to the above-mentioned embodiments of the display panel, and the repeated parts will not be repeated.

In summary, in the display panel and display device provided by the embodiments of the present disclosure, the first pixel definition layer has first opening regions, and the quantum dot patterns are located in at least some of the first opening regions, that is, the first pixel definition layer and the plurality of quantum dot patterns are located in the same layer. Compared with the black pixel definition layer in the related art, since the first pixel definition layer does not contain black dye, the first pixel definition layer is set thicker and can also be penetrated and cured by ultraviolet light. Therefore, compared with the related art, the thickness of the first pixel definition layer can be increased, thereby increasing the thickness of the quantum dot pattern and improving the conversion rate of the quantum dot pattern. In addition, the reflectivity of the first pixel definition layer is greater than that of the black pixel definition layer, and the light emitted by the quantum dot pattern will be reflected when reaching the first pixel definition layer. The first side surface of the first pixel definition layer surrounding the first opening region is a concave surface, and the light emitted by the quantum dot pattern is reflected after reaching the concave surface. The propagation direction of the reflected light has a smaller angle with the direction perpendicular to the base substrate, which is more conducive to making the light reaching the first side surface emitted along the vertical viewing angle of the display panel, making full use of the light reflected by the first side surface, and improving the front light extraction efficiency of the display panel.

Although preferred embodiments of the present invention have been described, additional changes and modifications may occur to these embodiments once those skilled in the art are aware of the basic inventive concepts. Therefore, it is intended that the appended claims be interpreted as including the preferred embodiment as well as all changes and modifications that fall within the scope of the present invention.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalent technologies, the present disclosure is also intended to include these modifications and variations.

1. A display panel, comprising:
a base substrate comprising a plurality of pixel regions arranged in an array along a first direction and a second direction; wherein each of the pixel regions comprises a plurality of sub-pixel regions, and the first direction intersects the second direction;
a plurality of light-emitting devices located on a side of the base substrate and corresponding one-to-one to the plurality of sub-pixel regions;
a first pixel definition layer located on a side of the light-emitting devices away from the base substrate and comprising first opening regions corresponding one-to-one to the plurality of sub-pixel regions; wherein a reflectivity of the first pixel definition layer to light in a wavelength range of 400 nanometers to 700 nanometers is greater than 20%; the first pixel definition layer comprises a first side surface surrounding the first opening region, and the first side surface is a concave surface recessed in the first pixel definition layer;
a plurality of quantum dot patterns located on the side of the light-emitting devices away from the base substrate and located in at least some of the first opening regions.

2. The display panel according to claim 1, wherein, cross-sectional areas of the first opening region parallel to a plane where the base substrate is located gradually increase in a direction perpendicular to the base substrate and pointing from the base substrate to the first pixel definition layer.

3. The display panel according to claim 2, wherein the first side surface is a portion of a spherical surface.

4. The display panel according to claim 3, wherein the first pixel definition layer comprises a first surface facing the base substrate and a second surface facing away from the base substrate; a width d1 of the first opening region on the first surface and a width d2 of the first opening region on the second surface in the first direction or in the second direction, and a thickness h1 of the first pixel definition layer in the direction perpendicular to the base substrate satisfy:
$$\frac{d 2}{2} = \sqrt{{( \frac{d 1}{2} )}^{2} + h {1}^{2}} .$$

5. The display panel according to claim 4, wherein in the first direction or in the second direction, the width d1 of the first opening region on the first surface, the width d2 of the first opening region on the second surface, and a maximum width L1 of the first pixel definition layer satisfy:
$$\frac{d 2}{2} \leq \frac{d 1}{2} + \frac{L 1}{3} .$$

6. The display panel according to claim 5, wherein the maximum width L1 of the first pixel definition layer in the first direction or in the second direction and the thickness h1 of the first pixel definition layer in the direction perpendicular to the base substrate satisfy:
$$\frac{1}{2} \leq \frac{L 1}{h 1} \leq 1 .$$

7. The display panel according to claim 4, wherein the width d1 of the first opening region on the first surface in the first direction or in the second direction, and the thickness h1 of the first pixel definition layer in the direction perpendicular to the base substrate satisfy:
$$\frac{1}{12} \leq \frac{h 1}{d 1} \leq \frac{1}{4} .$$

8. The display panel according to claim 1, wherein a thickness h1 of the first pixel definition layer in a direction perpendicular to the base substrate is greater than or equal to 10 micrometers and less than or equal to 20 micrometers.

9. The display panel according to claim claim 1, further comprising:
a color filter layer on a side of the quantum dot patterns away from the base substrate;
wherein a thickness of the color filter layer in a direction perpendicular to the base substrate is greater than or equal to 1 micrometer and less than or equal to 4 micrometers.

10. The display panel according to claim claim 1, further comprising:
a plurality of encapsulation layers between the first pixel definition layer and the light-emitting devices;
wherein at least one of the plurality of encapsulation layers comprises:
a number of n low-refractive index encapsulation sub-layers, and
a number of n+1 high-refractive index encapsulation sub-layers;
wherein n is an integer greater than or equal to 1; a refractive index of the high-refractive index encapsulation sub-layer is greater than a refractive index of the low-refractive index encapsulation sub-layer; and the low-refractive index encapsulation sub-layers and the high-refractive index encapsulation sub-layers are arranged alternately.

11. The display panel of claim 10, wherein the high-refractive index encapsulation sub-layer comprises an inorganic material, and the low-refractive index encapsulation sub-layer comprises an organic material.

12. (canceled)

13. The display panel according to claim 11, wherein the refractive index of the high-refractive index encapsulation sub-layer is greater than or equal to 1.6 and less than or equal to 1.85.

14. (canceled)

15. (canceled)

16. The display panel according to claim 11, wherein the refractive index of the low-refractive index encapsulation sub-layer is greater than or equal to 1.4 and less than or equal to 1.5.

17. The display panel according to claim 11, wherein at least one of the low-refractive index encapsulation sub-layers further comprises a plurality of scattering particles.

18. The display panel according to claim 17, wherein a mass percentage of the scattering particles is greater than or equal to 5% and less than or equal to 10%.

19. The display panel according to claim 17, wherein the plurality of scattering particles comprise one or a combination of following:
zinc oxide particles, titanium dioxide particles, hollow silica dioxide particles, non-hollow silica dioxide particles, nanosilicate particles, or porogen particles.

20. The display panel according to claim 17, wherein the refractive index of the low-refractive index encapsulation sub-layer is greater than or equal to 1.1 and less than or equal to 1.4.

21. The display panel according to claim 10, wherein the encapsulation layer closest to the quantum dot patterns comprises the low-refractive index encapsulation sub-layers and the high-refractive index encapsulation sub-layers.

22. (canceled)

23. A display panel according to any one of claims 1 to 6, 11, 12, 14, 15, 18-22 claim 1, wherein the plurality of light-emitting devices are blue light-emitting devices; the plurality of sub-pixel regions comprise: a plurality of red sub-pixel regions, a plurality of blue sub-pixel regions, and a plurality of green sub-pixel regions; the quantum dot patterns are only located in the first opening regions corresponding to the red sub-pixel regions and the green sub-pixel regions.

24. A display device, comprising the display panel according to claim 1.
